(19) United States
(12) Patent Application Publication
(10) Pub. No.: US 2021/0146438 A1
(43) Pub. Date: May 20, 2021

(54) METAL MATERIAL AND IN-SITU EXSOLUTION MODIFICATION METHOD FOR A SURFACE THEREOF

(71) Applicant: Institute of New Materials, Guangdong Academy of Sciences, Guangzhou, Guangdong (CN)

(72) Inventors: Yapeng Zhang, Guangzhou, Guangdong (CN); Taikai Liu, Guangzhou, Guangdong (CN); Chunming Deng, Guangzhou, Guangdong (CN); Yingchun Xie, Guangzhou, Guangdong (CN); Ziqian Deng, Guangzhou, Guangdong (CN); Min Liu, Guangzhou, Guangdong (CN)

(21) Appl. No.: 16/982,042

(22) PCT Filed: Mar. 23, 2020
(86) PCT No.: PCT/CN2020/080643

§ 371 Date: Sep. 18, 2020

(30) Foreign Application Priority Data
Jun. 14, 2019 (CN) 201910519553.0

(51) Int. Cl. B22F 9/02; C23C 4/134; B01J 23/89; C23C 14/30; C23C 4/08; B22F 9/04; B22F 1/00

(52) U.S. Cl. CPC B22F 9/026; C23C 4/134; B01J 23/892; C23C 14/30; B82Y 40/00; B22F 9/04; B01J 23/8906; B01J 23/8913; B22F 1/0088; C23C 4/08

(57) ABSTRACT

The invention discloses a method for in-situ exsolution modification of a surface of a metal material, which comprises steps of : (1) a substrate metal powder are fully mixed with a metal powder for modification to obtain a raw material powder; (2) the raw material powder obtained in step (1) are prepared into a metal material by a preparation method at a non-equilibrium condition; (3) a heat treatment on the metal material prepared in step (2) is performed so that the metal material reaches an equilibrium state; after cooling to room temperature, a doped phase is exsolved to the surface of the metal material to obtain a modified metal material.

### FIELD OF THE INVENTION

This invention relates to the field of preparation and modification of materials, in particular to a method for in-situ exsolution modification of a surface of a metal material to enhance the electrochemical performance of the metal material.

### BACKGROUND OF THE INVENTION

At present, noble metal catalysts have shown excellent electrochemical catalytic properties, but they are not suitable for large-scale applications due to cost problems. Traditional catalysts such as Fe, Co, Ni, Cu, etc. also have certain catalytic activities. Because of their large reserves and low cost, they are widely used in the catalytic industry. The catalyst industry is continuously evolving. Fuel cells, water electrolysis, organic catalysis and other technologies have increasing demands for catalyst activity. At the present stage, the use of a single, traditional catalyst can no longer meet the catalytic performance requirements in these technologies. It is thus necessary to modify materials to improve their performance. However, the modified particles prepared by conventional material modification methods such as electrodeposition, magnetron sputtering, and heteroatom substitution do not interact strongly with the base material. As a result, although the modified material has improved initial performance, its stability usually decreases. Some of the aforementioned modification methods are only suitable to carry out in the laboratory; they are not suitable for large-scale production. Therefore, there is an urgent need for a novel, stable metal surface modification method.

In-situ exsolution method is a new material modification method that is extremely stable and efficient. This method merely requires a small amount of noble metals to modify the traditional metal catalysts to improving the performance of these catalysts while maintaining their stability. Therefore, the in-situ exsolution method is anticipated to have a good application prospect in the field of material preparation and modification. At present, in China, there has been no report on metal surface modification by in-situ exsolution.

### SUMMARY OF THE INVENTION

In view of the above, the objective of the present invention is to provide a method for in-situ exsolution modification of a surface of a metal material to enhance electrochemical performance. The method is aimed at the modification of traditional metal catalysts and can be applied to various fields of material processing and preparation. The modification can be accomplished through doping only a small amount of noble metals. The method is convenient to operate and is low in cost. It shows clear value in the laboratory and has good application prospects.
In order to achieve the aforementioned objective, the technical solution adopted by the invention is as follows: a method for in-situ exsolution modification of a surface of a metal material, the method comprises steps of:
(1) mixing a substrate metal and a metal powder for modification to obtain a raw material powder;
(2) preparing the raw material powder obtained in step (1) into a metal material by a preparation method at a non-equilibrium condition;
(3) performing a heat treatment on the metal material prepared in step (2) so that the metal material reaches an equilibrium state; a doped phase is exsolved to the surface of the metal material to obtain a modified metal material.

The design principle of the present invention is as follows: in-situ exsolution is a new method for material modification. It refers to the preparation of a metal material by mixing doped particles with a substrate under a non-equilibrium condition, followed by a change of conditions so that the metal material reaches equilibrium. Due to the different properties of the doped metal and the substrate, the doped phase is exsolved from the bulk phase to the surface to form a nano-island pinning structure. The exsolved nanoparticles are closely attached to the substrate and interact strongly with the substrate. As a result, the modified metal has a highly stable structure. Furthermore, the nanoparticle islands increase the surface roughness of the substrate and the specific surface area, thereby increases the number of catalytic active sites and the catalytic performance of the metal material.

Preferably, in step (1), the substrate metal is at least one selected from the group consisting of Mn, Fe, Co, Ni, Cu, and Zn.

Preferably, in step (1), the metal for modification is at least one selected from the group consisting of Mo, Ru, Rh, Pd, Ag, Ir, Pt, and Au.

Preferably, in step (1), a metal for modification in the raw material powder has a mass percentage of 0.1%-15%. When the amount is less than 0.1%, it is difficult to ensure the metal for modification will be exsolved out of the surface to achieve modification. When the amount is more than 15%, the cost will be high; furthermore, the particles are likely to accumulate at the surface, reducing modification quality.

Preferably, in step (2), the preparation method at the non-equilibrium condition is at least one selected from the group consisting of supersonic flame spraying, explosion spraying, atmospheric plasma spraying, supersonic plasma spraying, (ultra) low pressure plasma spraying, plasma spray—physical vapor deposition, electron beam deposition, cold spraying and laser 3D printing.

Preferably, in step (3), the heat treatment has a temperature of 500° C.-900° C., duration of the heat treatment is 1 hour-24 hours.

Preferably, in step (1), the mixing is mechanical mixing or spray granulation.

Preferably, in step (3), the heat treatment is under vacuum, in a protective atmosphere, or in a reducing atmosphere.

The present invention also provides a metal material prepared by the aforementioned modification method. The in-situ exsolution modified metal material of the present invention has a wide range of applications. It can be applied to improve the catalytic performance of metal catalysts in a number of aspects, including their hydrogen and oxygen evolution reactions, oxygen reduction reactions, hydrogen oxidation reactions, organic compound catalytic cracking reactions, and the like. The metal material has distinctive structural stability and high commercial value.

Preferably, a doped metal is pinned on the surface of the substrate metal; the doped metal has a nanostructure. The exsolved nanoparticles are closely attached to the substrate and interact strongly with the substrate. As a result, the modified metal has a highly stable structure. Furthermore, the nanoparticle islands increase the surface roughness of the substrate and the specific surface area, thereby increases the number of catalytic active sites and the catalytic performance of the metal material.

Compared with the prior art, the beneficial effects of the present invention are as follows:

(1) the modification method of the present invention is easy to perform: the modified metal catalyst can be obtained by doping and mixing only a small amount of metal for modification to prepare the raw material, followed by heat treatment.

(2) A wide range of preparation techniques can be used in the method of the present invention, including supersonic flame spraying, explosion spraying, atmospheric plasma spraying, supersonic plasma spraying, (ultra) low pressure plasma spraying, plasma spray—physical vapor deposition, electron beam deposition, cold spraying, laser 3D printing, etc. The method of the present invention is widely applicable.

(3) The in-situ exsolution modified metal material of the present invention has a wide range of applications. It can be applied to improve the catalytic performance of metal catalysts in a number of aspects, including their hydrogen and oxygen evolution reactions, oxygen reduction reactions, hydrogen oxidation reactions, organic compound catalytic cracking reactions, and the like. The metal material has distinctive structural stability and high commercial value.

### BRIEF DESCRIPTION OF DRAWINGS

FIG. 1 is an SEM image of a surface of an untreated coated catalyst obtained in embodiment 1 according to the present invention;

FIG. 2 is an SEM image of the surface of the coated catalyst after 4 hours of heat treatment according to embodiment 1 of the present invention.

FIG. 3 is an SEM image of the surface of the coated catalyst after 8 hours of heat treatment according to embodiment 1 of the present invention.

FIG. 4 is an EDX analysis result of the surface of the untreated coated catalyst obtained in embodiment 1 according to the present invention.

FIG. 5 is an EDX analysis result of the surface of the coated catalyst after 8 hours of heat treatment according to embodiment 1 of the present invention.

FIG. 6 is an SEM image of a surface of an untreated coated catalyst obtained in embodiment 2 according to the present invention.

FIG. 7 is an SEM image of the surface of the coated catalyst after 4 hours of heat treatment according to embodiment 2 of the present invention.

FIG. 8 is an SEM image of the surface of the coated catalyst after 8 hours of heat treatment according to embodiment 2 of the present invention.

FIG. 9 is an EDX result of a cross-sectional surface layer of the coated catalyst after 8 hours of heat treatment according to embodiment 2 of the present invention;

FIG. 10 is an EDX result of the cross-section of a bulk phase of the coated catalyst after 8 hours of heat treatment according to embodiment 2 of the present invention.

### DETAILED DESCRIPTION OF ILLUSTRATED EMBODIMENTS

In order to better illustrate the objective, technical solutions and advantages of the present invention, the present invention will be further described with reference to the drawings and embodiments.

### Embodiment 1

As an embodiment of the metal material of the present invention, the metal material of this embodiment was prepared by the following method:

287.5 g Ni metal powder was weighed as a substrate metal powder, and 25 g Ag metal powder was weighed as a modification metal powder. The mass percentage of the modification metal powder was 8%. The powders weighed were transferred into a V-shaped mixer and mixed for 24 hours at a rotating speed of 10 r min⁻¹. The fully mixed material will be used at a later stage as a raw material powder. A coated catalyst was prepared from the aforementioned raw material powder by an atmospheric plasma spraying equipment (APS). Under the protection of 20 ml min⁻¹ of hydrogen, two batches of the coated catalyst prepared were heated to 800° C. and kept at this temperature for 4 hours and 8 hours respectively. After sintering was completed, a quartz tube was opened and samples were taken out; these samples are the metal materials modified by in-situ exsolution.

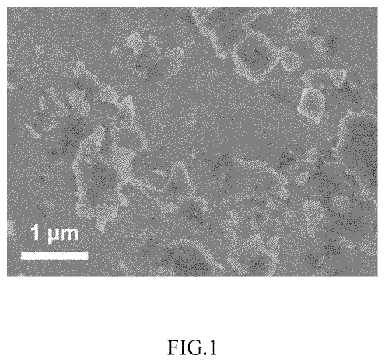

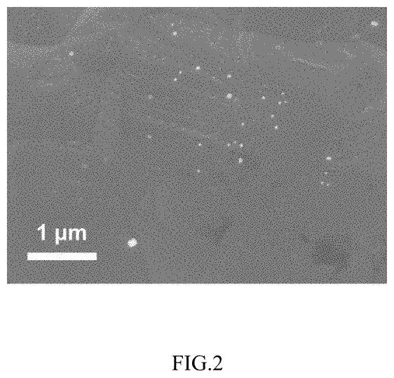

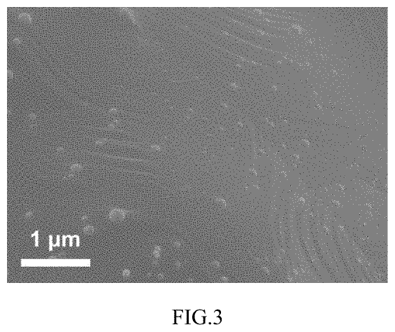

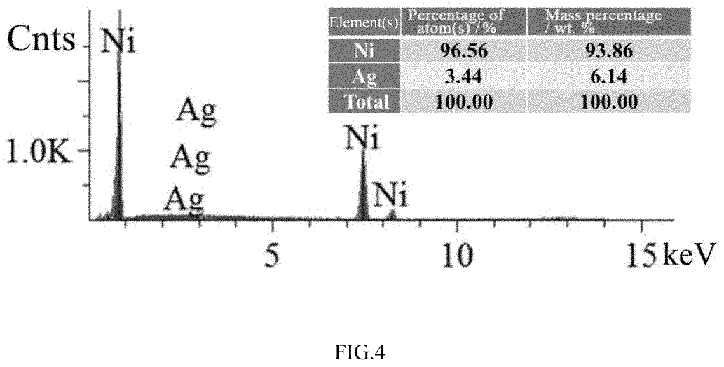

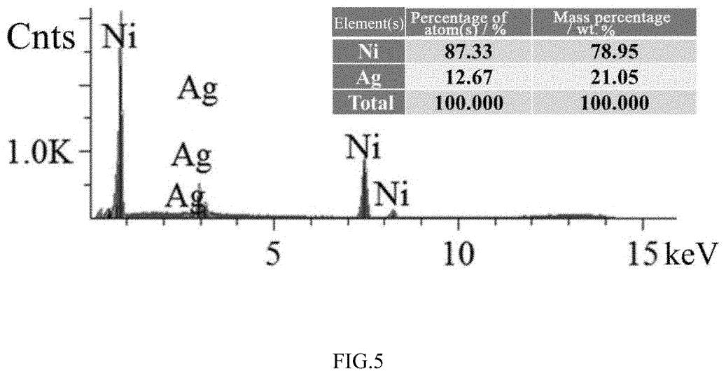

SEM tests were performed on surfaces of the original coated catalyst without heat treatment, the coated catalyst after the 4 h heat treatment and the coated catalyst after the 8 h heat treatment respectively. As shown in FIGS. 1-3, there were many undissolved powdered particles on the surface of the untreated coated catalyst. After the 4 h heat treatment, the undissolved particles on the surface visibly decreased, the surface became smooth and grain boundaries began to emerge. At the same time, a small number of exsolved small particles appeared at some grain boundaries. After the 8 h heat treatment for 8 hours, the undissolved irregular particles had completely disappeared, and a large number of spherical nano-Ag particles were pinned at the grain boundaries of Ni. EDX analysis was performed on SEM-selected surface areas of the untreated catalyst and the catalyst after the 8 h heat treatment. As shown in FIGS. 4-5, the amount of Ag on the surface increased significantly after heat treatment, that is, the exsolved nanoparticles in FIG. 3 are Ag particles used for modification. The aforementioned results indicate that a modified catalyst having an in-situ exsolved nano-pinning structure can be obtained by an in-situ exsolution modification method.

### Embodiment 2

As an embodiment of a metal material of the present invention, the metal material of this embodiment was prepared by the following method:

475 g Ni metal powder was weighed as substrate metal powders and 25 g Ag metal powder was weighed as a modification metal powder, and the mass percentage of the modification metal powder was 5%. The powders weighed were transferred into a ball milling tank and mixed with water, which acts as a dispersant, for 6 hours at a rotating speed of 400 r min⁻¹ to allow thorough mixing. The mixture was then dried in an oven to produce a raw material powder for later use. A coated catalyst was prepared from the aforementioned raw material powders through adopting a cold spraying (CS) equipment. The coated catalyst prepared was sealed in a quartz tube, the quartz tube was vacuumized at room temperature and then refilled with 300 mbar argon. The sealed quartz tube was heated to 800° C. in a muffle furnace, followed by kept at this temperature for 4 hours and 8 hours respectively. After sintering was completed, the quartz tube was opened and samples were taken out; these samples are the metal materials modified by in-situ exsolution.

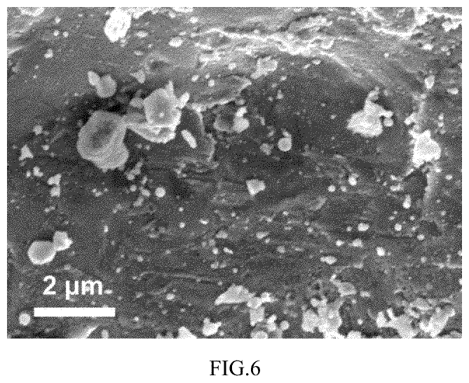

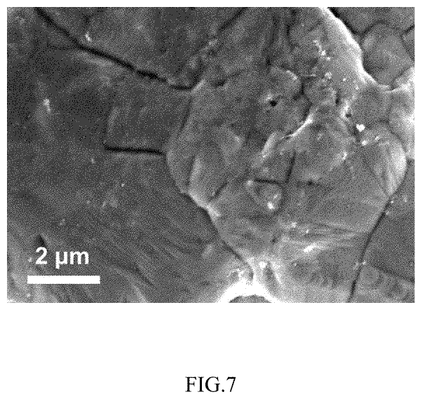

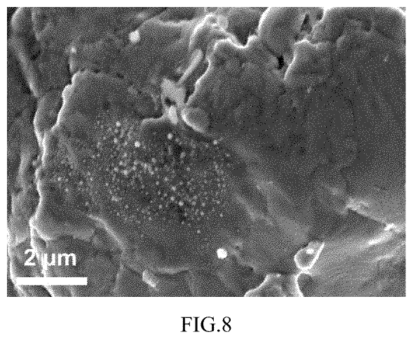

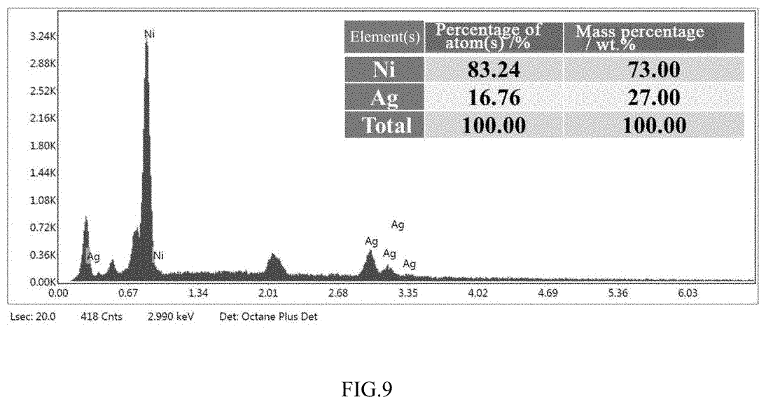

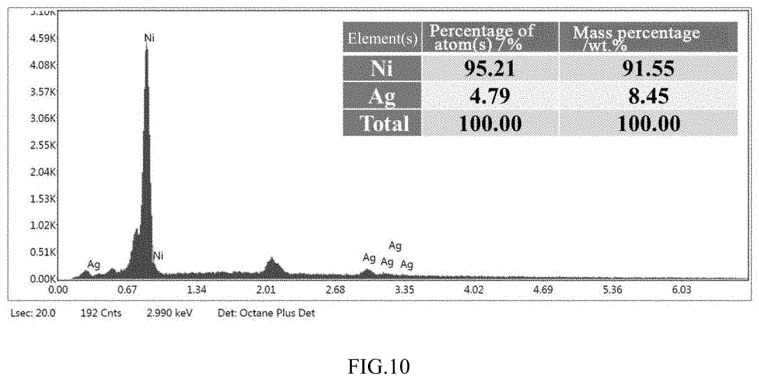

During the preparation process, SEM tests were performed on the surfaces of the original coated catalyst without heat treatment, the coated catalyst after the 4 h heat treatment and the coated catalyst after 8 h heat treatment respectively. As shown in FIGS. 6-8, there were many undissolved powder particles on the surface of the untreated coated catalyst. After the 4 h heat treatment, the undissolved particles on the surface visibly decreased, the surface became smooth and the grain boundaries began to emerge. At the same time, a small number of small particles appeared at some grain boundaries. After the 8 h heat treatment, the undissolved irregular particles had completely disappeared, and a large number of spherical nano-Ag particles were pinned at the grain boundaries of Ni. EDX tests were performed on a cross-sectional surface layer and a cross-sectional bulk phase of the coated catalyst after the 8 h heat treatment (FIGS. 9-10). It can be seen that the amount of Ag on the surface layer increased significantly after heat treatment, that is, Ag in the coated bulk phase tended to diffuse toward the surface. The aforementioned results indicate that a modified catalyst having an in-situ exsolved nano-pinning structure can be obtained by an in-situ exsolution modification method.

### Embodiment 3

As an embodiment of a metal material of the present invention, the metal material of this embodiment was prepared by the following method:

499.5 g Fe metal powder was weighed as substrate metal powder and 0.5 g Au metal powder was weighed as modification metal powder, the percentage mass of modification metal powder was 0.1 mass %; the powder weighed was transferred into a ball milling tank and mixed with water, which acts as a dispersant, for 6 hours at a rotating speed of 400 r min⁻¹ to allow thorough mixing. The mixture was then dried in an oven to produce a raw material powder for later use. A coated catalyst was prepared from the aforementioned raw material powders through adopting an atmospheric plasma spraying. The coated catalyst prepared was sealed in a quartz tube, the quartz tube was vacuumized at room temperature and then refilled with 300 mbar argon. The sealed quartz tube was heated to 500° C. in a muffle furnace, followed by kept at this temperature for 8 hours and 12 hours respectively. After sintering was completed, the quartz tube was opened and samples were taken out; these samples are the metal materials modified by in-situ exsolution.

The analysis of the surface morphology of the metal materials modified by in-situ exsolution prepared was the same as that of embodiment 1 and embodiment 2, and will not be repeated here.

### Embodiment 4

According to an embodiment of a metal material of the present invention, the metal material in this embodiment was prepared by the following method:

425 g Co metal powder was weighed as substrate metal powder and 75 g Pt metal powder was weighed as modification metal powder, the percentage mass of modification metal powder was 15%; the powder weighed was transferred into a ball milling tank and mixed with water, which acts as a dispersant, for 6 hours at a rotating speed of 400 r min⁻¹ to allow thorough mixing. The mixture was then dried in an oven to produce a raw material powder for later use. A coated catalyst was prepared from the aforementioned raw material powders by electron beam deposition; the coated catalyst prepared was sealed in a quartz tube, the quartz tube was vacuumized at room temperature and then refilled 300 mbar argon. The sealed quartz tube was heated to 900° C. in a muffle furnace, followed by kept at this temperature for 4 hours and 8 hours respectively. After sintering was completed, the quartz tube was opened and samples were taken out; these samples are the metal materials modified by in-situ exsolution.

The analysis of the surface morphology of the metal materials modified by in-situ exsolution prepared was the same as that of embodiment 1 and embodiment 2, and will not be repeated here.

It should be finally noted that the aforementioned embodiments merely illustrate the technical solutions of the present invention. They are not intended to limit the scope of protection of the present invention. Although the present invention has been described in detail with reference to the preferred embodiments, those of ordinary skill in the art should understand that the technical solutions of the present invention can be modified or equivalently replaced without departing from the essence and scope of the technical solutions of the present invention.

1. A method for in-situ exsolution modification of a surface of a metal material, characterized in that the method comprises steps of:
(1) mixing a substrate metal and a metal powder for modification to obtain a raw material powder;
(2) preparing the raw material powder obtained in step (1) into a metal material by a preparation method at a non-equilibrium condition;
(3) performing a heat treatment on the metal material prepared in step (2) so that the metal material reaches an equilibrium state; a doped phase is exsolved to the surface of the metal material to obtain a modified metal material.

2. The method according to claim 1, characterized in that in step (1), the substrate metal is at least one selected from the group consisting of Mn, Fe, Co, Ni, Cu, and Zn.

3. The method according to claim 1, characterized in that in step (1), the metal for modification is at least one selected from the group consisting of Mo, Ru, Rh, Pd, Ag, Ir, Pt, and Au.

4. The method according to claim 1, characterized in that in step (1), a metal for modification in the raw material powder has a mass percentage of 0.1%-15%.

5. The method according to claim 1, characterized in that in step (2), the preparation method at the non-equilibrium condition is at least one selected from the group consisting of supersonic flame spraying, explosion spraying, atmospheric plasma spraying, supersonic plasma spraying, (ultra) low pressure plasma spraying, plasma spray—physical vapor deposition, electron beam deposition, cold spraying and laser 3D printing.

6. The method according to claim 1, characterized in that in step (3), the heat treatment has a temperature of 500° C.-900° C., duration of the heat treatment is 1 hour-24 hours.

7. The method according to claim 1, characterized in that in step (1), the mixing is mechanical mixing or spray granulation.

8. The method according to claim 1, characterized in that in step (3), the heat treatment is under vacuum, in a protective atmosphere, or in a reducing atmosphere.

9. A metal material prepared by the method according to any claim 1.

10. The metal material according to claim 9, characterized in that a doped metal is pinned on the surface of the substrate metal; the doped metal has a nanostructure.
